(19) United States
(12) Patent Application Publication
(10) Pub. No.: US 2025/0048650 A1
(43) Pub. Date: Feb. 6, 2025

(54) SEMICONDUCTOR DEVICES

(71) Applicant: SAMSUNG ELECTRONICS CO., LTD., Suwon-si (KR)

(72) Inventors: Seulji SONG, Suwon-si (KR); Youngmin KO, Suwon-si (KR); Hodae KIM, Suwon-si (KR)

(21) Appl. No.: 18/653,139

(22) Filed: May 2, 2024

(30) Foreign Application Priority Data
Aug. 1, 2023 (KR) 10-2023-0100665

(51) Int. Cl. H10B 63/00

(52) U.S. Cl. CPC H10B 63/24; H10B 63/80

(57) ABSTRACT

A semiconductor device includes first and second conductive lines respectively extending in first and second directions on a substrate. Cell structures are respectively between the first and second conductive lines and include first and second electrodes and a selector layer. First capping layers cover side surfaces of the first conductive lines and first side surfaces of the cell structures in the second direction. First interlayer insulating layers fill spaces between the first conductive lines and between the cell structures in the second direction and contact the first capping layers. Second capping layers cover second side surfaces of the cell structures in the first direction and side surfaces of the second conductive lines. Second interlayer insulating layers fill spaces between the cell structures and between the second conductive lines in the first direction and contact the second capping layers. The first and second interlayer insulating layers have different carbon contents.

### CROSS-REFERENCE TO RELATED APPLICATION(S)

This application claims priority under 35 U.S.C. § 119 to Korean Patent Application No. 10-2023-0100665, filed on Aug. 1, 2023 in the Korean Intellectual Property Office, the disclosure of which is incorporated by reference in its entirety herein.

### 1. TECHNICAL FIELD

The present inventive concept relates to a semiconductor device.

### 2. DISCUSSION OF RELATED ART

Computer eXpress Link (CXL) is a new standardized interface created to use devices, such as CPU, GPU, Al accelerator, memory, and the like, more efficiently. A semiconductor device capable of storing high-capacity data is required to increase the performance and capacity in such a CXL interface environment. Accordingly, research is being conducted concerning a Selector Only Memory (SOM) to increase the data storage capacity of the semiconductor device SUMMARY

An aspect of the present disclosure is to provide a semiconductor device having increased reliability.

According to an embodiment of the present disclosure, a semiconductor device includes first conductive lines extending in a first direction on a substrate. Second conductive lines extend in a second direction on the first conductive lines. The second direction is perpendicular to the first direction. Cell structures are respectively disposed between the first conductive lines and the second conductive lines. Each of the cell structures includes a first electrode, a selector layer including a chalcogenide material, and a second electrode, that are sequentially stacked. First capping layers cover side surfaces of the first conductive lines and first side surfaces of the cell structures in the second direction. First interlayer insulating layers fill spaces between the first conductive lines and between the cell structures in the second direction and directly contact the first capping layers. Second capping layers cover second side surfaces of the cell structures in the first direction and side surfaces of the second conductive lines. Second interlayer insulating layers fill spaces between the cell structures and between the second conductive lines in the first direction and directly contact the second capping layers. The first interlayer insulating layers and the second interlayer insulating layers have different carbon contents from each other.

According to an embodiment of the present disclosure, a semiconductor device includes a first conductive lines extending in a first direction on a substrate. Second conductive lines extend in a second direction on the first conductive lines. The second direction intersects the first direction. Cell structures are respectively disposed between the first conductive lines and the second conductive lines. Each of the cell structures includes a first electrode, a selector layer including a chalcogenide material, and a second electrode, that are sequentially stacked. Capping layers cover side surfaces of the cell structures. The capping layers include nitride. First interlayer insulating layers fill spaces between the first conductive lines and between the cell structures in the second direction. Second interlayer insulating layers fill spaces between the cell structures and between the second conductive lines in the first direction. At least one of the first interlayer insulating layers and the second interlayer insulating layers includes a low-x material having a carbon content in a range of about 15% to about 25%. The first interlayer insulating layers and the second interlayer insulating layers directly contact the capping layers.

According to an embodiment of the present disclosure, a semiconductor device, includes first conductive lines extending in a first direction on a substrate. Second conductive lines extend in a second direction on the first conductive lines. The second direction intersects the first direction. Cell structures are respectively disposed between the first conductive lines and the second conductive lines. Each of the cell structures includes a first electrode, a selector layer including a chalcogenide material, and a second electrode that are sequentially stacked. Capping layers cover at least side surfaces of the cell structures. First interlayer insulating layers fill spaces between the first conductive lines and between the cell structures in the second direction and directly contact the capping layers. Second interlayer insulating layers fill spaces between the cell structures and between the second conductive lines in the first direction and directly contact the capping layers. At least one of the first interlayer insulating layers and the second interlayer insulating layer includes a low-κ material including a carbon content in a range of about 15% to about 25% and having an oxygen content that is higher than the carbon content.

### BRIEF DESCRIPTION OF DRAWINGS

The above and other aspects, features, and advantages of embodiments of the present disclosure will be more clearly understood from the following detailed description, taken in conjunction with the accompanying drawings:

FIG. 1 is a schematic plan view of a semiconductor device according to an example embodiment;

FIGS. 2A and 2B are schematic cross-sectional views of a semiconductor device according to example embodiments;

FIGS. 3A and 3B are schematic perspective views of a semiconductor device according to example embodiments;

FIG. 4 is a schematic perspective view of a semiconductor device according to an example embodiment;

FIGS. 5A and 5B are diagrams for illustrating an interlayer insulating layer of a semiconductor device according to example embodiments;

FIG. 6 is a graph for illustrating reliability of a semiconductor device according to an example embodiment;

FIGS. 7A to 7H are schematic perspective views illustrating a method of manufacturing a semiconductor device according to example embodiments; and

FIG. 8 is a block diagram illustrating a memory system including a semiconductor device according to an example embodiment.

### DETAILED DESCRIPTION OF EMBODIMENTS

Hereinafter, with reference to the accompanying drawings, example embodiments of the present disclosure will be described as follows.

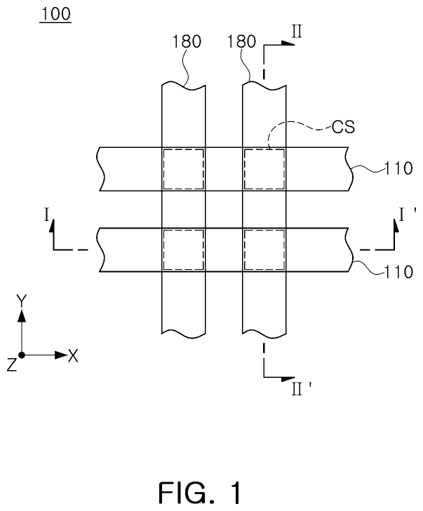

FIG. 1 is a schematic plan view of a semiconductor device according to example embodiments.

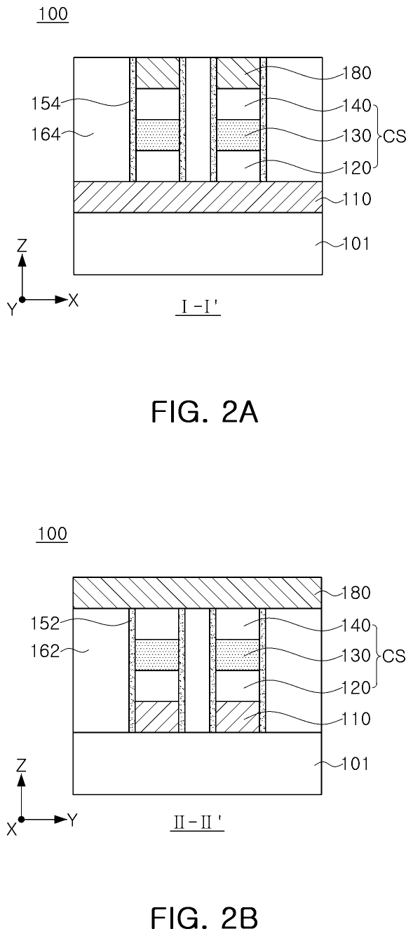

FIGS. 2A and 2B are schematic cross-sectional views of a semiconductor device according to example embodiments. FIG. 2A illustrates a cross-section taken along the line I-I′ in FIG. 1, and FIG. 2B illustrates a cross-section taken along the line II-II′ in FIG. 1.

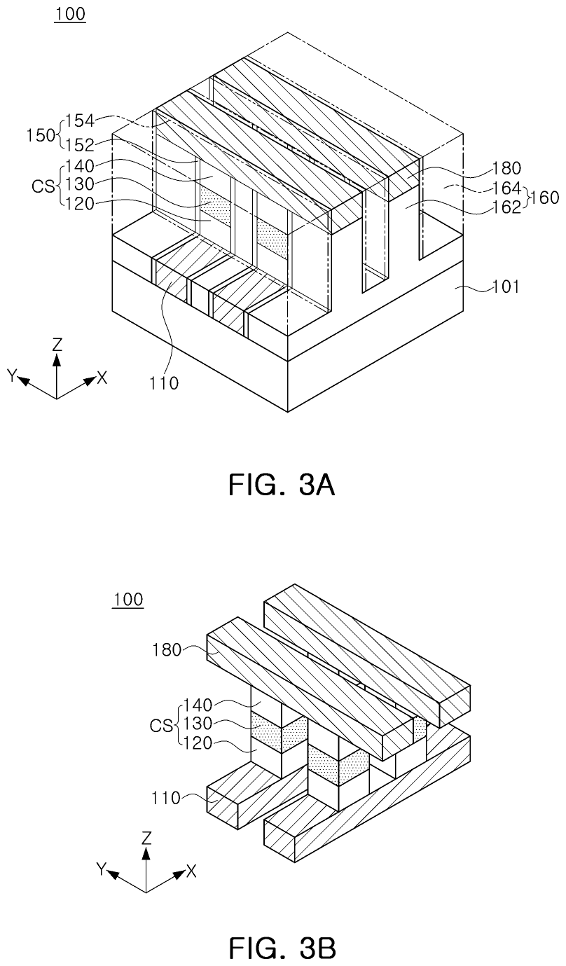

FIGS. 3A and 3B are schematic perspective views of a semiconductor device according to example embodiments. FIG. 3B illustrates only some of the components in FIG. 3A.

Referring to FIGS. 1 to 3B, in an embodiment a semiconductor device 100 may include a substrate 101, first conductive lines 110 on the substrate 101, second conductive lines 180 crossing the first conductive lines 110, cell structures CS respectively disposed between the first conductive lines 110 and the second conductive lines 180, capping layers 150 covering side surfaces of the cell structures CS, and interlayer insulating layers 160 filling spaces between the cell structures CS.

In the semiconductor device 100, each of the cell structures CS may comprise a memory cell. In an embodiment, the semiconductor device 100 may be a memory device having a 3D crosspoint array structure, and may be, for example, a single select device memory (SOM). However, embodiments of the present disclosure are not necessarily limited thereto.

In an embodiment, the substrate 101 may have an upper surface extending in the X direction and the Y direction. The X direction may be a first direction and the Y direction may be a second direction intersecting the X direction. For example, in an embodiment the Y direction may be perpendicular to the X direction. However, embodiments of the present disclosure are not necessarily limited thereto and the Y direction may intersect the X direction at various different angles. In an embodiment, the substrate 101 may include a semiconductor material, such as a Group IV semiconductor, a Group III-V compound semiconductor, or a Group II-VI compound semiconductor. For example, in an embodiment the group IV semiconductor may include silicon, germanium, or silicon-germanium. The substrate 101 may be provided as a bulk wafer, an epitaxial layer, an epitaxial layer, a Silicon On Insulator (SOI) layer, or a Semiconductor On Insulator (SeOI) layer.

In an embodiment, the first conductive lines 110 may extend on the substrate 101 in one direction, such as in the X direction, and may be disposed to be spaced apart from each other in the Y direction. Each of the first conductive lines 110 may comprise a word line.

In an embodiment, the second conductive lines 180 may cross the first conductive lines 110 on the first conductive lines 110 and extend in one direction, such as in the Y direction, and may be disposed to be spaced apart from each other in the X direction. In an embodiment, each of the second conductive lines 180 may comprise a bit line. While FIG. 1 shows two first conductive lines 110 and two second conductive lines 180, embodiments of the present disclosure are not necessarily limited thereto and the number of first conductive lines 110 and second conductive lines 180 may vary.

The first conductive lines 110 and the second conductive lines 180 may include the same material or different materials from each other. The first conductive lines 110 and the second conductive lines 180 may include a conductive material such as a metal material and/or a doped semiconductor material. In an embodiment, the metal material may include, for example, tungsten (W). In some example embodiments, the first conductive lines 110 and/or the second conductive lines 180 may further include a diffusion barrier film, and for example, the diffusion barrier film may include tungsten nitride (WN), tantalum nitride (TaN), titanium nitride (TiN), or combinations thereof. In some example embodiments, the first conductive lines 110 and/or the second conductive lines 180 may include polycrystalline silicon or a metal silicide material. However, embodiments of the present disclosure are not necessarily limited thereto.

The cell structures CS may be disposed between the first conductive lines 110 and the second conductive lines 180 in regions in which the first conductive lines 110 and the second conductive lines 180 intersect each other. Although the cell structures CS are illustrated as having a rectangular columnar shape, a shape of the cell structures CS is not necessarily limited thereto, and may have various shapes such as a cylinder, etc. In an embodiment, each of the cell structures CS may include a first electrode 120, a selector layer 130, and a second electrode 140, sequentially stacked from the first conductive line 110 (e.g., in a Z direction). The cell structures CS may directly contact the first conductive lines 110 through lower surfaces, such as a lower surface of the first electrode 120, and directly contact the second conductive lines 180 through upper surfaces, such as upper surfaces of the second electrode 140.

In an embodiment, a lower surface of the first electrode 120 may directly contact the first conductive line 110 and an upper surface of the first electrode 120 may directly contact the selector layer 130. An upper surface of the second electrode 140 may directly contact the second conductive line 180 and a lower surface of the second electrode 140 may directly contact the selector layer 130. In an embodiment, the first electrode 120 and the second electrode 140 may electrically connect the selector layer 130 to the first conductive line 110 and the second conductive line 180, respectively, and prevent a material of the selector layer 130 from being diffused and lost. In an embodiment, the first electrode 120 and the second electrode 140 may include a conductive material, such as carbon (C), etc. In an embodiment in which the first electrode 120 and the second electrode 140 are both formed of a metal material, the material of the selector layer 130 may diffuse along grain boundaries of the first electrode 120 and the second electrode 140. However, in an embodiment in which the first electrode 120 and the second electrode 140 are both formed of carbon (C), the diffusion of the selector layer 130 can be prevented.

The selector layer 130 may have memory characteristics and selector characteristics for switching at the same time. In an embodiment, the selector layer 130 may have a variable threshold voltage, and the threshold voltage may vary according to a direction of a write operation due to a difference in trap concentration. Accordingly, the semiconductor device 100 may not include a separate switching element or a resistive layer such as a phase change material layer, in addition to the selector layer 130.

In an embodiment, the selector layer 130 may include a material layer capable of changing a threshold voltage according to the direction of a write operation. For example, in an embodiment the selector layer 130 may include an Ovonic Threshold Switching (OTS) material. The selector layer 130 may be in an amorphous state, and may maintain the amorphous state during operation of the semiconductor device 100.

In an embodiment, the selector layer 130 may include a chalcogenide material. Accordingly, the selector layer 130 may include, for example, at least one of group 16 elements such as sulfur (S), selenium (Se), and tellurium (Te). Alternatively, the selector layer 130 may include at least one of group 14 elements such as silicon (Si) and germanium (Ge), and group 15 elements such as arsenic (As) and antimony (Sb), or include the same in addition to the group 16 elements. For example, the selector layer 130 may include at least one compound selected from sulfur (S), selenium (Se), tellurium (Te), silicon (Si), germanium (Ge), arsenic (As), and antimony (Sb). In some example embodiments, the selector layer 130 may further include a metallic material.

In some example embodiments, the selector layer 130 may further include at least one additional element selected from indium (In), boron (B), carbon (C), nitrogen (N), and oxygen (O). For example, the selector layer 130 may include germanium (Ge), selenium (Se), arsenic (As), and indium (In).

In an embodiment, the selector layer 130 may be formed of a single layer or a multilayer including at least one of binary materials such as GeSe, GeS, AsSe, AsTe, AsS SiTe, SiSe, SiS, GeAs, SiAs, SnSe, and SnTe, ternary materials such as GeAsTe, GeAsSe, AlAsTe, AlAsSe, SiAsSe, SiAsTe, GeSeTe, GeSeSb, GaAsSe, GaAsTe, InAsSe, InAsTe, SnAsSe, and SnAsTe, quaternary materials such as GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTI, GeAsSeSn, GeAsSeZn, GeAsTeIn, GeAsTeGa, GeAsTeAl, GeAsTeTI, GeAsTeSn, and GeAsTeZn, quintuple materials such as GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSeTeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSEAlSn, GeAsSeTlZn, and GeAsSeTlSn, GeAsSeZnSn, and sextuple materials such as GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, and GeAsSeSAlSn. However, embodiments of the present disclosure are not necessarily limited thereto.

In an embodiment, the capping layers 150 may include first capping layers 152 and second capping layers 154. The first capping layers 152 may cover side surfaces (e.g., lateral side surfaces) of the cell structures CS in a Y direction, and may cover side surfaces (e.g., lateral side surfaces) of the first conductive lines 110 in the Y direction. In an embodiment, the second capping layers 154 may cover side surfaces (e.g., lateral side surfaces) of the cell structures CS in an X direction, and may cover side surfaces (e.g., lateral side surfaces) of the second conductive lines 180 in the X direction. Since the first capping layers 152 cover side surfaces of the first conductive lines 110 and the second capping layers 154 cover side surfaces of the second conductive lines 180, the capping layers 152 and the second capping layers 154 may be positioned on different levels from each other (e.g., in the Z direction). For example, a level of upper ends of the first capping layers 152 may be different from (e.g., lower than in the Z direction) a level of upper ends of the second capping layers 154, and a level of lower ends of the first capping layers 152 may be different from (e.g., lower than in the Z direction) a level of lower ends of the second capping layers 154. In an embodiment, the capping layers 150 may completely cover the side surfaces of the cell structures CS, to prevent diffusion of a material of the selector layer 130 along the interfaces between the layers.

The capping layers 150 may be formed of an insulating material. The first capping layers 152 and the second capping layers 154 may be formed of the same or different materials from each other. For example, in an embodiment the capping layers 150 may include at least one compound selected from SiN, SiO₂, SiON, SiBN, SiCN, SiOCN, Al₂O₃, AlN, and AlON. However, embodiments of the present disclosure are not necessarily limited thereto. In some example embodiments, the capping layers 150 may include silicon nitride. In some example embodiments, each of the capping layers 150 may be a single material layer. For example, in an example embodiment in which the first capping layer 152 is formed of two stacked layers, both of the two layers may be formed of SiN.

The interlayer insulating layers 160 may be gap-fill layers filling spaces between the cell structures CS. In an embodiment, the interlayer insulating layers 160 may include first interlayer insulating layers 162 and second interlayer insulating layers 164. The first interlayer insulating layers 162 may fill spaces between the cell structures CS and between the first conductive lines 110 in the Y direction. The second interlayer insulating layers 164 may fill spaces between the cell structures CS and between the second conductive lines 180 in the X direction. The interlayer insulating layers 160 may directly contact the capping layers 150.

In an embodiment, at least one of the first interlayer insulating layers 162 and the second interlayer insulating layers 164 may include a low dielectric constant (low-x) material having a content of carbon (C) in a range of about 15% to about 25%, for example, in a range of about 19% to about 23%. Hereinafter, a content of an element may mean an atomic percentage. The low-x material may have a lower dielectric constant than silicon dioxide (SiO₂). In the low-x material, in comparative embodiments in which the content of carbon (C) is lower than the above-described range, it may be difficult to maintain film quality, making it difficult to realize a desired low-x film, and in comparative embodiments in which the content of carbon (C) is higher than the above-described range, a contraction rate may increase, so that defects such as peeling of the capping layers 150 may occur. In an embodiment, the low-x material may be, for example, SiOC. For example, in the low-x material, a content of oxygen (O) may be in a range of about 42% to about 52%, and a content of silicon (Si) may be in a range of about 25% to about 36%. The low-x material may have the highest content of oxygen (O), the next highest content of silicon (Si), and the lowest content of carbon (C).

In some example embodiments, both the first interlayer insulating layers 162 and the second interlayer insulating layers 164 may include the low-x material. In some example embodiments, the first interlayer insulating layers 162 may include the low-x material, and the second interlayer insulating layers 164 may include an insulating material that is different from that of the first interlayer insulating layers 162, such as an insulating material that is not a low-x material. In some example embodiments, the second interlayer insulating layers 164 may include the low dielectric constant material, and the first interlayer insulating layers 162 may include an insulating material, different from that of the second interlayer insulating layers 164, such as an insulating material that is not a low-x material.

For example, a dielectric constant of the insulating material may be greater than that of the low-x material. In some example embodiments, the insulating material may have a carbon (C) content, lower than that of the low-x material, or may not include carbon (C). In some example embodiments, the insulating material may have a carbon (C) content of about 5% or less, for example, about 0.1% to about 5%. In some example embodiments, the insulating material may be, for example, silicon nitride or silicon oxide. In some example embodiments, the insulating material may be, for example, at least one of SiN, SiON, SiC, SiCN, SiOCN, SiO₂, and Al₂O₃. However, embodiments of the present disclosure are not necessarily limited thereto.

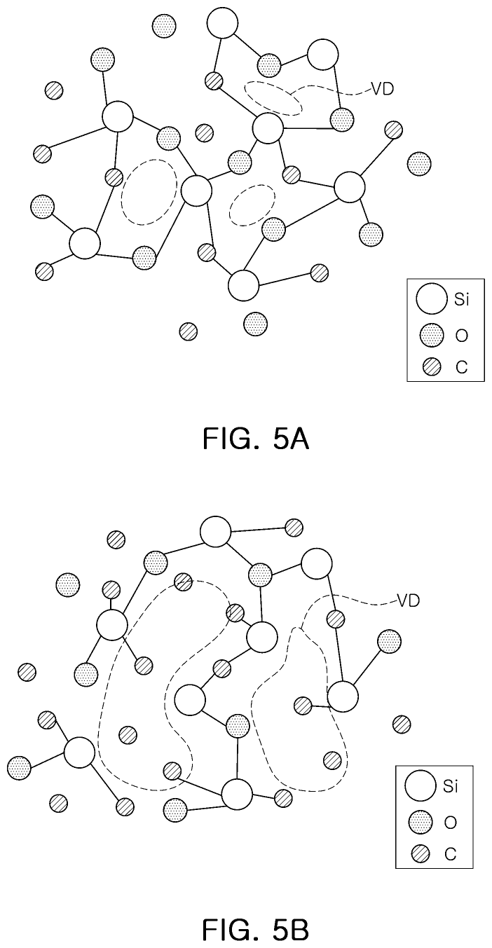

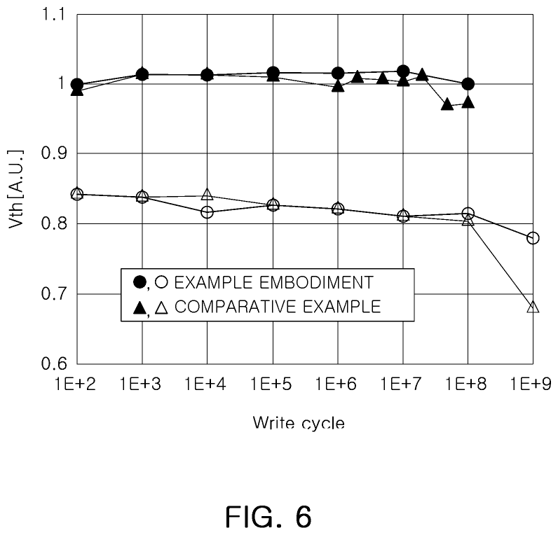

In the semiconductor device 100, since at least one of the first interlayer insulating layers 162 and the second interlayer insulating layers 164 includes the low-x material, the contraction rate may be relatively reduced in a subsequent process, and thus peeling between the capping layers 150 and the first and second electrodes 120 and 130 due to the interlayer insulating layers 160 may not occur. Therefore, diffusion of the material of the selector layer 130 due to the peeling may be prevented, and reliability of the semiconductor device 100 may be increased. This will be described in more detail below with reference to FIGS. 5A to 6.

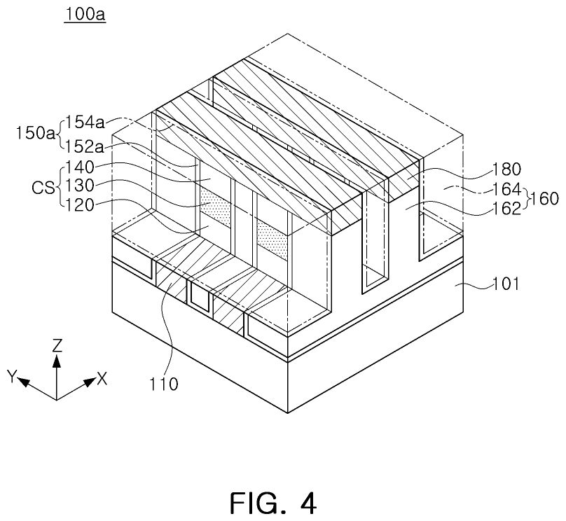

FIG. 4 is a schematic perspective view of a semiconductor device according to example embodiments.

Referring to FIG. 4, disposition of capping layers 150a in the semiconductor device 100a may be different from those of the example of FIGS. 2A to 3A. The capping layers 150a may be disposed to cover lower surfaces of the interlayer insulating layers 160. For example, in an embodiment the first capping layers 152a may cover an upper surface of the substrate 101 and lower surfaces of the first interlayer insulating layers 162 between adjacent cell structures CS along a Y direction. The second capping layers 154a may cover upper surfaces of the first interlayer insulating layers 162 and cover lower surfaces of the second interlayer insulating layers 164 between adjacent cell structures CS along an X direction.

FIGS. 5A and 5B are diagrams for illustrating an interlayer insulating layer of a semiconductor device according to example embodiments.

FIG. 6 is a graph for illustrating reliability of a semiconductor device according to example embodiments.

Referring to FIGS. 5A and 5B, a structure of a low carbon rate film and a high carbon rate film are schematically illustrated, respectively. In an embodiment in which the low carbon rate film illustrated in FIG. 5A, for example, a carbon content may be in a range of about 15% to about 25%, and in an embodiment in which the high carbon rate film illustrated in FIG. 5B, for example, a carbon content may be in a range of about 40% to about 52%.

In an embodiment, the interlayer insulating layer 160 (see FIGS. 1 to 3B) described above may be formed through a densification process such as a UV process or an annealing process, after being coated by a spin-on-glass (SOG) process or the like. During the densification process, the interlayer insulating layers 160 may partially contract, and a contraction rate may vary depending on the carbon content. In the case of the low carbon rate film, the contraction rate may be relatively small, and in the case of the high carbon rate film, the contraction rate may be relatively high. This phenomenon can be explained as follows.

A basic molecular structure of the material for forming the interlayer insulating layer 160 is (RSiO_{1.5})n, where R may be obtained by binding a ligand such as hydrogen (H), methyl group, ethyl group, vinyl group, or aryl group. The molecules may form a thin film by forming crosslinks through a condensation reaction in which reaction by-products such as hydrogen (H₂) or water (H₂O) escape. In this case, as a size of the ligand increases, that is, as the content of carbon increases, direct bonding of Si-O-Si may be hindered so that a larger network may be formed. FIGS. 5A and 5B illustrate such a Si-O-Si ring structure. In the case of the high-carbon-rate film, internal voids (VD) may be larger than those of the low-carbon-rate film, and accordingly, the contraction rate may increase in a subsequent densification process.

Referring to FIG. 6, results of an endurance test performed on a semiconductor device including a low carbon rate film and a high carbon rate film having element contents as illustrated in Table 1 below as the interlayer insulating layer 160 are illustrated. The carbon content of the low carbon rate film is 21.3%, the oxygen content is 47.6%, and the silicon content is 31.1%. The carbon content of the high carbon rate film is 48.6%, the oxygen content is 30.7%, and the silicon content is 20.7%. The contraction rate of the low-carbon film by the UV process is 3.00%, and the contraction rate of the high-carbon film by the UV process is 5.60%.

TABLE 1

| | Content in low carbon | Content in high carbon |
|---|---|---|
| | rate film [%] | rate film [%] |
| Carbon (C) | 21.3 | 48.6 |
| Oxygen O) | 47.6 | 30.7 |
| Silicon (Si) | 31.1 | 20.7 |

FIG. 6 illustrates a change in a threshold voltage Vth according to an increase in write cycles for an Example embodiment including a low carbon rate film and a Comparative example embodiment including a high carbon rate film. The threshold voltage Vth is represented by a reset voltage Vreset and a set voltage Vset, respectively.

FIG. 6 illustrates a change in a threshold voltage Vth according to an increase in write cycles for an Example embodiment including a low carbon rate film and a Comparative example embodiment including a high carbon rate film. The threshold voltage Vth is represented by a reset voltage Vreset and a set voltage Vset, respectively.

As shown in FIG. 6, in the case of the Comparative example embodiment, the threshold voltage suddenly decreases after 10⁸ cycles, whereas in the Example embodiment, there is no sudden change in the threshold voltage. The difference in the threshold voltage after 10⁸ cycles between the Comparative example embodiment and the Example embodiment is based on a contraction rate in a densification process being relatively large in the high carbon rate film of the Comparative example. Thus, lateral stress of the interlayer insulating layer 160 increases in the Comparative example, so that adhesion defects between the capping layer 150 and the first and second electrodes 120 and 140 may occur. When electrical stress is accumulated, as peeling occurs between the capping layer 150 and the first and second electrodes 120 and 140, and the material of the selector layer 130 diffuses towards, for example, a direction of the second electrode 140, reliability may be deteriorated. In contrast, in the case of the Example embodiment, since the contraction rate of the interlayer insulating layer 160 is relatively small, an interfacial peeling phenomenon may be prevented, and thus endurance characteristics of up to 10 cycles may be secured. From these results, it can be confirmed that reliability is increased when the carbon (C) content of the interlayer insulating layer 160 is in a range of about 15% to about 25%, for example, in a range of about 19% to about 23%.

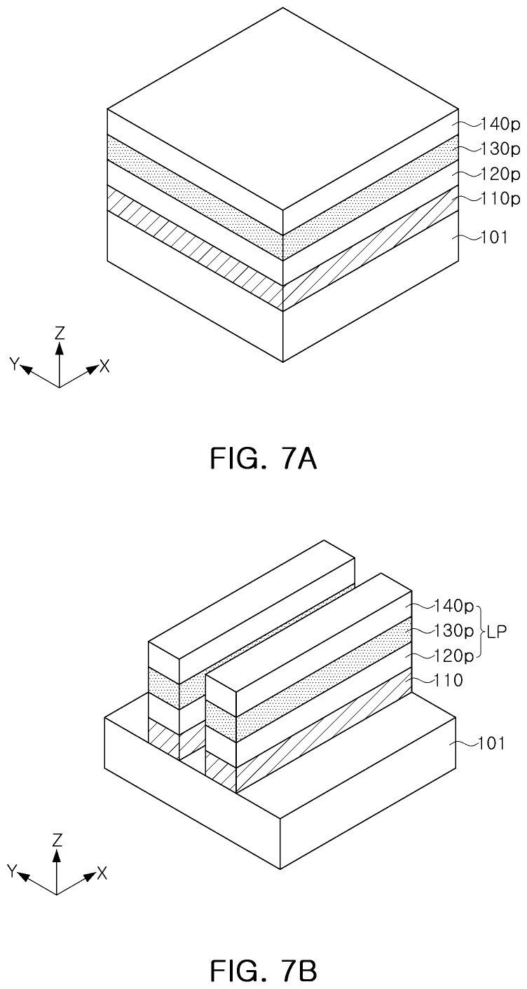

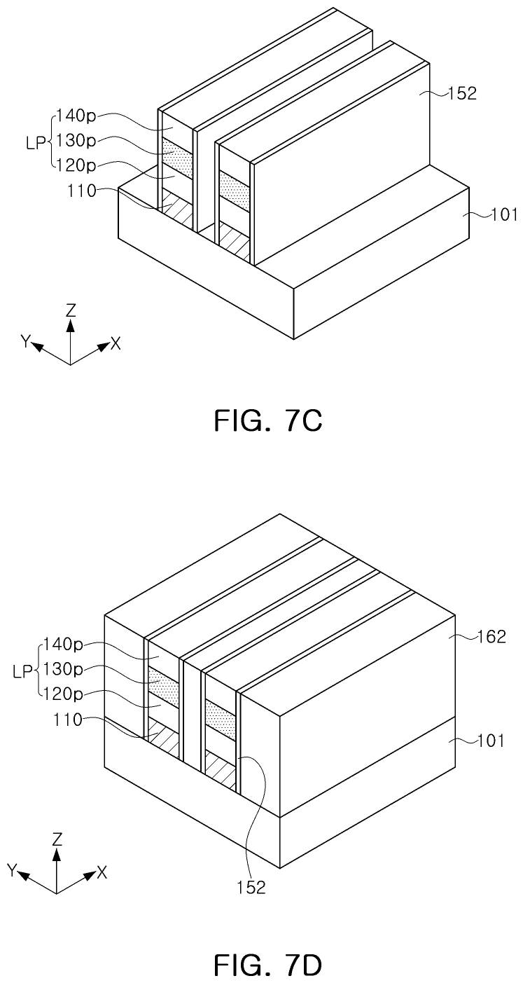

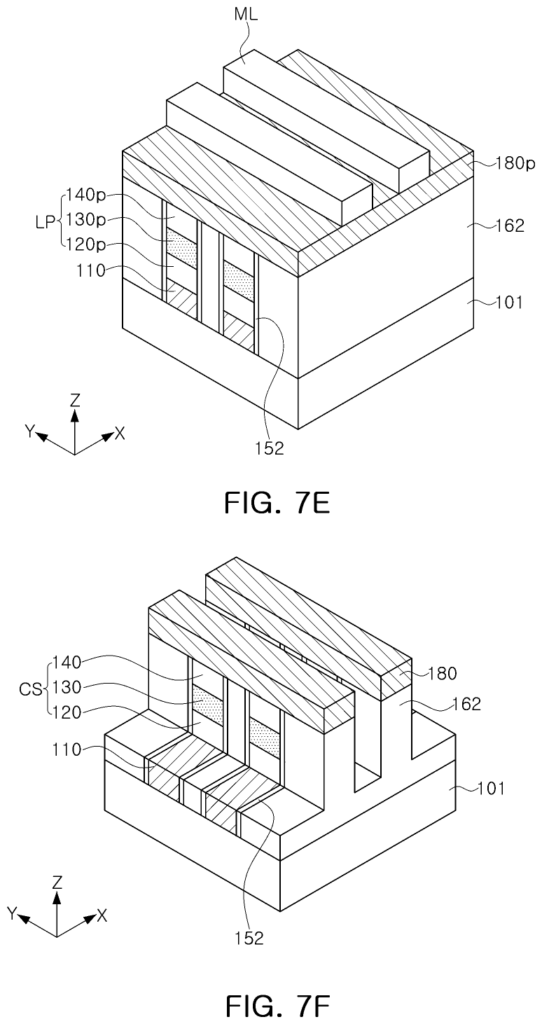

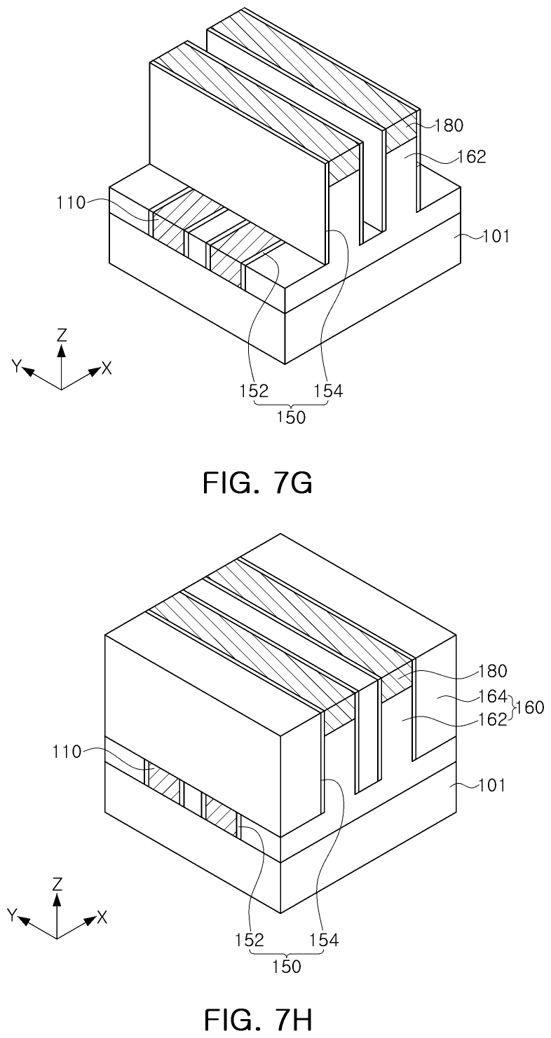

FIGS. 7A to 7H are schematic perspective views illustrating a method of manufacturing a semiconductor device according to example embodiments,

Referring to FIG. 7A, in an embodiment a stack structure of a first conductive layer 110p, a first electrode layer 120p, a preliminary selector layer 130p, and a second electrode layer 140p may be formed on a substrate 101.

The first conductive layer 110p, the first electrode layer 120p, the preliminary selector layer 130p, and the second electrode layer 140p may be layers, patterned in a subsequent process, to form the first conductive lines 110, the first electrode 120, the selector layer 130, and the second electrode 140 of FIG. 3, respectively. In an embodiment, the layers may be formed by, for example, a sputtering process. In example embodiments, thickness of the layers may vary widely from that illustrated and embodiments of the present disclosure are not necessarily limited thereto.

Referring to FIG. 7B, first conductive lines 110 and line patterns LP may be formed by patterning the stacked structure.

In an embodiment, the stack structure may be patterned in a line shape extending in an X direction by an etching process. As a result, the first conductive layer 110p may be patterned to form first conductive lines 110, and the first electrode layer 120p, the preliminary selector layer 130p, and the second electrode layer 140p may form line patterns LP on the first conductive lines 110.

Referring to FIG. 7C, first capping layers 152 may be formed on side surfaces of the first conductive lines 110 and side surfaces of the line patterns 1P.

The first capping layers 152 may be formed to cover side surfaces (e.g., lateral side surfaces) of the first conductive lines 110 in a Y direction and side surfaces (e.g., lateral side surfaces) of the line patterns LP in a Y direction. In an embodiment, the first capping layers 152 may be formed using, for example, a chemical vapor deposition (CVD) process. The first capping layers 152 may be, for example, SiN layers.

Referring to FIG. 7D, first interlayer insulating layers 162 filling spaces between the first conductive lines 110 and between the line patterns LP may be formed.

In an embodiment, the first interlayer insulating layers 162 may be formed through, for example, spin-coating using an SOG process or depositing using flowable CVD, and then formed through the above-described densification process. The densification process may be performed by a UV process or an annealing process at a temperature of 400° C. or higher. Thereafter, a planarization process may be further performed to expose the second electrode layers 140p.

In some example embodiments, as described above, the first interlayer insulating layers 162 may be formed of a low-carbon film, and in this embodiment, a contraction rate may be relatively reduced to prevent peeling of the first capping layers 152. In addition, since it is not necessary to perform plasma treatment on the first capping layers 152, to increase bonding characteristics, damage to the preliminary selector layer 130p due to the treatment process may be prevented.

Referring to FIG. 7E, a second conductive layer 180p may be formed on the line patterns LP and the first interlayer insulating layers 162 and a mask layer ML may be formed.

The second conductive layer 180p may be a layer which is patterned in a subsequent process to form the second conductive lines 180 of FIG. 3. In an embodiment, the mask layer ML. may be formed by being patterned in a line shape extending in a Y direction on the second conductive layer 180p.

Referring to FIG. 7F, cell structures CS and second interconnection lines 180 may be formed by patterning the second conductive layer 180p and the line patterns LP using a mask layer ML.

A portion of each of the lower second conductive layer 180p, the line patterns LP, the first capping layers 152, and the first interlayer insulating layers 162 may be removed using the mask layer ML. As a result, in an embodiment cell structures CS having a columnar shape and second interconnection lines 180 having a line shape may be formed.

Referring to FIG. 7G, second capping layers 154 may be formed on side surfaces (e.g., lateral side surfaces) of the cell structures CS and side surfaces (e.g., lateral side surfaces) of the second conductive lines 180.

The second capping layers 154 may be formed to cover (e.g., completely cover) side surfaces of the cell structures CS in the X direction and side surfaces of the second conductive lines 180 in the X direction. In an embodiment, the second capping layers 154 may be formed using, for example, a CVD process. The second capping layers 154 may be, for example, a SiN layer.

Referring to FIG. 7H, second interlayer insulating layers 164 filling spaces between the cell structures CS and between the second conductive lines 180 may be formed.

The second interlayer insulating layers 164 may be formed to fill spaces between exposed side surfaces of the second capping layers 154. In an embodiment, the second interlayer insulating layers 164 may be formed through, for example, spin-coating using an SOG process or depositing using a flow CVD process and then formed through the above-described densification process. Thereafter, a planarization process may be further performed to expose the second conductive lines 180.

In some example embodiments, the second interlayer insulating layers 164 may be formed of a low-carbon film as described above, and in this embodiment, a contraction rate may be reduced, thereby preventing the second capping layers 154 from being peeled off.

The semiconductor device 100 of FIG. 1 may be manufactured through the above-described processes.

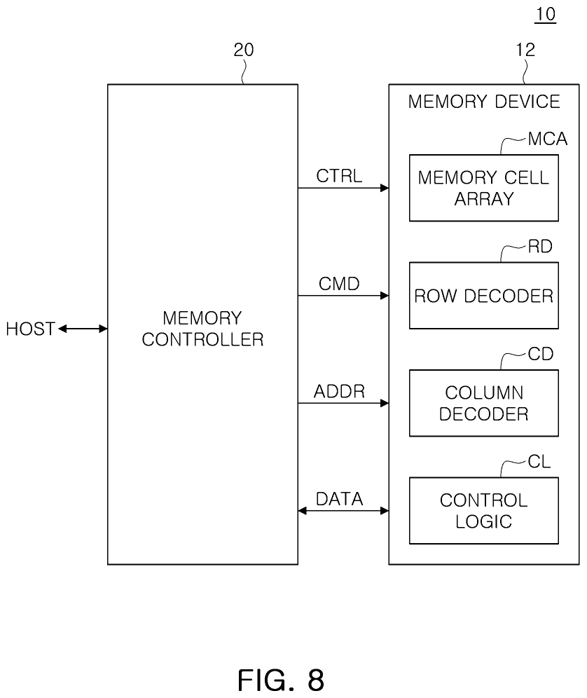

FIG. 8 is a block diagram illustrating a memory system including a semiconductor device according to example embodiments.

Referring to FIG. 8, the memory system 10 may include a memory device 12 and a memory controller 20. In an embodiment, the memory device 12 may include a memory cell array MCA, a row decoder RD, a column decoder CD, and a control logic CL.

In an embodiment, the memory controller 20 may read data stored in the memory device 12 in response to a write/read request from a HOST, or control the memory device 12 to write data to the memory device 12. The memory controller 20 may provide an address ADDR, a command CMD, and a control signal CTRL, to control program (or write), read, and erase operations of the memory device 12. In addition, data DATA to be written and data DATA to be read may be transmitted and received between the memory controller 20 and the memory device 12.

In an embodiment, the memory cell array MCA may include a plurality of memory cells disposed in regions in which a plurality of first signal lines and a plurality of second signal lines intersect. In example embodiments, the plurality of first signal lines may be a plurality of bit lines, and the plurality of second signal lines may be a plurality of word lines. However, embodiments of the present disclosure are not necessarily limited thereto. In other example embodiments, the plurality of first signal lines may be a plurality of word lines, and the plurality of second signal lines may be a plurality of bit lines. The memory cell array MCA may include Selector Only Memory cells, and may include the semiconductor device of FIGS. 1 to 4.

In an embodiment, the row decoder RD may drive a plurality of word lines comprising the memory cell array MCA, and the column decoder CD may drive a plurality of bit lines comprising the memory cell array MCA, In an embodiment, the row decoder RD may include a decoding means for decoding a row address, and a switch means for controlling switching in response to various row control signals according to the decoding results. The column decoder CD may include a decoding means for decoding a column address and a switch means for controlling switching in response to various column control signals according to the decoding results.

The control logic CL may control an overall operation of the memory device 12, and control the row decoder RD and the column decoder CD to perform an operation of selecting a memory cell from the memory cell array MCA. As an example, the control logic CL may generate a row address and a column address by processing an external address. The memory device 12 may include a power generating means for generating various write voltages and read voltages used in write and read operations. Under the control of the control logic CL, write voltages and read voltages may be provided to the memory cells through the row decoder RD and the column decoder CD.

As set forth above, by preventing peeling between electrodes and capping layers by optimizing a material of the interlayer insulating layer, a semiconductor device having increased reliability may be provided.

The various and advantageous advantages and effects of embodiments of the present disclosure are not limited to the above description. While non-limiting embodiments have been shown and described above, it will be apparent to those skilled in the art that modifications and variations could be made without departing from the scope of the present disclosure.

What is claimed is:

1. A semiconductor device, comprising:
first conductive lines extending in a first direction on a substrate;
second conductive lines extending in a second direction on the first conductive lines, the second direction is perpendicular to the first direction;
cell structures respectively disposed between the first conductive lines and the second conductive lines, each of the cell structures including a first electrode, a selector layer including a chalcogenide material, and a second electrode, that are sequentially stacked;
first capping layers covering side surfaces of the first conductive lines and first side surfaces of the cell structures in the second direction;
first interlayer insulating layers filling spaces between the first conductive lines and between the cell structures in the second direction and directly contacting the first capping layers;
second capping layers covering second side surfaces of the cell structures in the first direction and side surfaces of the second conductive lines; and
second interlayer insulating layers filling spaces between the cell structures and between the second conductive lines in the first direction and directly contacting the second capping layers,
wherein the first interlayer insulating layers and the second interlayer insulating layers have different carbon contents from each other.

2. The semiconductor device of claim 1, wherein any one of the first interlayer insulating layers and the second interlayer insulating layers comprise a low-x material having a carbon content in a range of about 15% to about 25%.

3. The semiconductor device of claim 2, wherein a remaining one of the first interlayer insulating layers and the second interlayer insulating layers comprises silicon nitride or silicon oxide.

4. The semiconductor device of claim 2, wherein the low-x material comprises SiOC.

5. The semiconductor device of claim 4, wherein the SiOC has a lower carbon content than a silicon content and an oxygen content.

6. The semiconductor device of claim 1, wherein:
levels of upper ends of the first capping layers are different from levels of upper ends of the second capping layers; and
levels of lower ends of the first capping layers are different from levels of lower ends of the second capping layers.

7. The semiconductor device of claim 1, wherein each of the first capping layers and the second capping layers is composed of a single material.

8. The semiconductor device of claim 1, wherein the first capping layers and the second capping layers comprise silicon nitride.

9. The semiconductor device of claim 1, wherein the selector layer comprises at least one compound selected from sulfur (S), selenium (Se), tellurium (Te), silicon (Si), germanium (Ge), arsenic (As), and antimony (Sb).

10. The semiconductor device of claim 1, wherein the first electrode and the second electrode comprise carbon.

11. The semiconductor device of claim 1, wherein the first electrode directly contacts the first conductive line and the selector layer, and the second electrode directly contacts the second conductive line and the selector layer.

12. A semiconductor device, comprising:
first conductive lines extending in a first direction on a substrate;
second conductive lines extending in a second direction on the first conductive lines, the second direction intersecting the first direction,
cell structures respectively disposed between the first conductive lines and the second conductive lines, each of the cell structures including a first electrode, a selector layer including a chalcogenide material, and a second electrode, that are sequentially stacked;
capping layers covering side surfaces of the cell structures, the capping layers including nitride;
first interlayer insulating layers filling spaces between the first conductive lines and between the cell structures in the second direction; and
second interlayer insulating layers filling spaces between the cell structures and between the second conductive lines in the first direction,
wherein at least one of the first interlayer insulating layers and the second interlayer insulating layers includes a low-x material having a carbon content in a range of about 15% to about 25%, and
the first interlayer insulating layers and the second interlayer insulating layers directly contact the capping layers.

13. The semiconductor device of claim 12, wherein the first interlayer insulating layers and the second interlayer insulating layers have different dielectric constants from each other.

14. The semiconductor device of claim 12, wherein:
any one of the first interlayer insulating layers and the second interlayer insulating layer comprises the low-x material; and
a remaining one of the first interlayer insulating layers and the second interlayer insulating layers includes a material having a carbon content, lower than a carbon of the low-x material, or does not include carbon.

15. The semiconductor device of claim 12, wherein the capping layers comprises:
first capping layers covering side surfaces of the first conductive lines and first side surfaces of the cell structures in the second direction; and
second capping layers covering second side surfaces of the cell structures in the first direction and side surfaces of the second conductive lines.

16. The semiconductor device of claim 12, wherein each of the capping layers is a single nitride layer.

17. The semiconductor device of claim 12, wherein a threshold voltage of the selector layer is changed according to a direction of a write operation.

18. A semiconductor device, comprising:
first conductive lines extending in a first direction on a substrate;
second conductive lines extending in a second direction on the first conductive lines, the second direction intersecting the first direction;
cell structures respectively disposed between the first conductive lines and the second conductive lines, each of the cell structures including a first electrode, a selector layer including a chalcogenide material, and a second electrode that are sequentially stacked;
capping layers covering at least side surfaces of the cell structures;
first interlayer insulating layers filling spaces between the first conductive lines and between the cell structures in the second direction and directly contacting the capping layers; and
second interlayer insulating layers filling spaces between the cell structures and between the second conductive lines in the first direction and directly contacting the capping layers, wherein at least one of the first interlayer insulating layers and the second interlayer insulating layer includes a low-K material including a carbon content in a range of about 15% to about 25% and having an oxygen content that is higher than the carbon content.

19. The semiconductor device of claim 18, wherein the low-x material comprises SiOC.

20. The semiconductor device of claim 18, wherein the first interlayer insulating layers comprise a material different from a material of the second interlayer insulating layers.
